(19) United States
(12) Patent Application Publication
(10) Pub. No.: US 2011/0169160 A1
(43) Pub. Date: Jul. 14, 2011

(54) REAL TIME MONITORING OF INDIUM BUMP REFLOW AND OXIDE REMOVAL ENABLING OPTIMIZATION OF INDIUM BUMP MORPHOLOGY

(75) Inventors: Frank Greer, Pasadena, CA (US); Todd J. Jones, Altadena, CA (US); Shouleh Nikzad, Valencia, CA (US); Thomas J. Cunningham, Pasadena, CA (US); Edward R. Blazejewski, Moorpark, CA (US); Matthew R. Dickie, Altadena, CA (US); Michael E. Hoenk, Valencia, CA (US)

(73) Assignee: CALIFORNIA INSTITUTE OF TECHNOLOGY, Pasadena, CA (US)

(21) Appl. No.: 13/005,751

(22) Filed: Jan. 13, 2011

Related U.S. Application Data
(60) Provisional application No. 61/294,754, filed on Jan. 13, 2010.

(51) Int. Cl. H01L 23/48; B23K 31/12; B23K 1/00; B23Q 15/013

(52) U.S. Cl. 257/737; 228/104; 228/19; 228/9; 257/E23.023

(57) ABSTRACT

A method, apparatus, system, and device provide the ability to form one or more solder bumps on one or more materials. The solder bumps are reflowed. During the reflowing, the solder bumps are monitored in real time. The reflow is controlled in real time, thereby controlling a morphology of each of the solder bumps. Further, the wetting of the solder bumps to a surface of the materials is controlled in real time.

### CROSS REFERENCE TO RELATED APPLICATIONS

This application claims the benefit under 35 U.S.C. Section 119(e) of the following co-pending and commonly assigned U.S. Provisional Patent Application:

U.S. Provisional Patent Application Ser. No. 61/294,754 filed on Jan. 13, 2010, by Todd J. Jones, Shouleh Nikzad, Thomas J. Cunningham, Edward R. Blazejewski, Matthew R. Dickie, Michael E. Hoenk and Harold Greer, entitled “REAL TIME MONITORING OF INDIUM BUMP RELFOW AND OXIDE REMOVAL ENABLING OPTIMIZATION OF INDIUM BUMP MORPHOLOGY” attorney's docket number 176.61-US-P1 (CIT-5524P), which application is incorporated by reference herein.

### STATEMENT REGARDING FEDERALLY SPONSORED RESEARCH AND DEVELOPMENT

The invention described herein was made in the performance of work under a NASA Contract, and is subject to the provisions of Public Law 96-517 (35 U.S.C. 202) in which the Contractor has elected to retain title.

### BACKGROUND OF THE INVENTION

1. Field of the Invention

The present invention relates generally to semiconductor devices, and in particular, to a method, apparatus, and article of manufacture for removing indium oxide from indium bumps used in flip chip hybridization (bump bonding), a process for reflowing these indium bumps into a highly wetted configuration, and a way to monitor this transition in real time.

2. Description of the Related Art

Flip chip hybridization, also known as bump bonding, is a packaging technique for microelectronic devices which directly connects an active element or detector to a substrate readout, face to face, eliminating the need for wirebonding. This approach is particularly well-suited for flight applications as it significantly reduces the dimensions of the final device. In order to make conductive links between the two parts, a solder material is used between the bond pads on each side. Solder bumps, composed of indium metal, are typically deposited by thermal evaporation onto the active regions of the device and substrate. The dimensions of the indium bumps are defined in a photolithographic templating process where excess material is removed by lift-off.

While indium bump technology has been a part of the electronic interconnect process field for many years, and has been extensively employed in the infrared imager industry, obtaining a reliable, high yield process for high density patterns of bumps can be quite difficult. One problem is the tendency of the indium bumps to oxidize during exposure to air. As the duration of air exposure can change depending on the process sequence used to fabricate the hybridized device, there can be a great deal of variability in the amount of oxidation that the bumps undergo prior to hybridization. As the level of oxidation increases, the contact resistance of the solder joint between the two halves of the flip-chip structure also increases, to the point where the bump may act as an open circuit preventing the assembled device from functioning correctly. Therefore, it is useful to have a reliable process that can remove this oxidized layer.

In addition, indium bumps are patterned using lithographic techniques. Occasionally, errors in the patterning process lead to misaligned or misshapen bumps. This is undesirable as it may affect the reliability of the electrical connection.

### SUMMARY OF THE INVENTION

To overcome the limitations in the prior art, and to overcome other limitations that will become apparent upon reading and understanding the present specification, the present invention discloses a method of forming one or more solder bumps on one or more materials comprising, reflowing the solder bumps; monitoring the reflowing of the solder bumps in real time; and controlling the reflowing in real time, based on the monitoring (e.g. observations or data from the monitoring), thereby controlling a morphology of each of the solder bumps.

The monitoring may be used to control wetting of the solder bumps to one or more surfaces of one or more materials in real time. The controlling may maximize or optimize wetting of the solder bumps to surfaces of the materials.

The solder bumps may be indium, for example.

The monitoring may use an optical camera that is positioned to view or optically image the solder bumps.

The materials may include one or more metal electrical contact pads that are lithographically patterned on a device, and the solder bumps may be at least partially positioned on the surfaces of the one or more metal electrical contact pads. The controlling may correct for imperfect alignment of the solder bumps relative to the one or more metal electrical contact pads.

The controlling may achieve the solder bumps that are contained on the one or more metal electrical contact pads.

At least two of the materials may include a first part and a second part of a device, and the method may comprise positioning the solder bumps on the first part only, or the first part and the second part, prior to the reflowing step; and connecting the second part to the first part using the solder bumps.

The controlling may achieve the morphology that is a pyramidal shape, a spherical shape, a truncated sphere, or a shape between a pyramidal shape and a spherical shape.

The controlling may vary one or more of a power, pressure, and exposure time of a plasma incident on the solder bumps.

The plasma may be a forming gas or a reducing gas, for example.

The method may further comprise using the plasma to remove an oxide from the solder bumps.

The present invention further discloses an apparatus for forming one or more solder bumps comprising a processing apparatus for heating and reflowing the solder bumps; and optics positioned to view and image solder bumps positioned on material in the processing apparatus.

The processing apparatus may be a plasma chamber and the heating and the reflowing results from exposing the solder bumps to plasma in the plasma chamber, for example.

The apparatus may further comprise a computer processor or process for varying one or more of a list of processing conditions or parameters that cause heating or reflow of the solder bumps in the processing apparatus, wherein the list includes e.g., a power, pressure, gas composition, and exposure time of the plasma incident on the solder bumps, in response to an image of the solder bumps obtained from the camera.

The optics may include a camera operating at video rate speeds and has a resolution that is at least ten (10) times larger than a size of the solder bumps prior to the heating and the reflowing. The optics may be positioned to enable monitoring of the reflowing and heating of the solder bumps in real-time and remotely from outside the processing apparatus, or inside the processing apparatus.

The present invention further comprises a device, including parts of the device; and one or more solder bumps connecting at least two of the parts, wherein the solder bumps are maximally wetted to at least one of the parts, so that a contact angle of the solder bump with respect to the at least one of the parts is as close to zero as possible. The device may be a semiconductor, a microelectronic, a nanoelectronic device, or a microelectromechanical (MEMS) device, for example. The parts may include a substrate and a detector, and the substrate may be a detector read out, for example.

### BRIEF DESCRIPTION OF THE DRAWINGS

Referring now to the drawings in which like reference numbers represent corresponding parts throughout:

FIG. 1(a) is an image of indium bumps on metal contact pads before reflow, wherein the inset is a close up view of one of the indium bumps, showing a bar-shaped indium bump on the metal contact pad, according to one or more embodiments of the present invention;

FIG. 1(b) is an image of the indium bumps after reflow, under controlled reflow conditions, wherein the inset is a close up showing that the indium bump has transformed into a spherical shape, according to one or more embodiments of the present invention, wherein the exposure time must be carefully controlled as exceeding the ideal value by as little as twenty [20] seconds could result in evaporation of the indium bump;

FIG. 1(c) is a close up showing that when conditions are manipulated to a condition where the exposure time to the plasma has been increased and the power of the plasma is decreased, poor reflow conditions result, according to one or more embodiments of the present invention;

FIG. 2(a) is an image of indium bumps on metal contact pads after short reflow times, according to one or more embodiments of the present invention;

FIG. 2(b) is a close up view of FIG. 2(a) showing a single indium bump that is a dome shape, having a dome height (at the top-most vertex) that is 6-7 micrometers tall, according to one or more embodiments of the present invention;

FIG. 2(c) is an image of indium bumps on metal contact pads after long reflow times, leading to “ball” shaped indium bumps, according to one or more embodiments of the present invention;

FIG. 2(d) is a close up view of FIG. 2(c) showing a single indium bump that is a ball shape, according to one or more embodiments of the present invention;

FIG. 3(a) plots XPS (X-ray photoelectron spectroscopy) results, plotting XPS count (number of electrons counted/detected) vs. binding energy (eV [electron volts]) of an indium bump to a metal contact pad, for an untreated indium bump (no reflow), according to one or more embodiments of the present invention;

FIG. 3(b) plots XPS results, plotting XPS count vs. binding energy (eV) of an indium bump to a metal contact pad, for a treated (with reflow) indium bump, so that the indium bump has a dome shape, according to one or more embodiments of the present invention;

FIG. 3(c) plots XPS results, plotting XPS count vs. binding energy (eV) of an indium bump to a metal contact pad, for a treated indium (with reflow) indium bump, so that the indium bump has a ball shape, according to one or more embodiments of the present invention; FIGS. 4(a) and 4(b) are photographs illustrating a microscope boomstand used to position a lens system to image the solder bumps in a plasma chamber (e.g., an inductively coupled H₂ plasma system), according to one or more embodiments of the present invention.

FIG. 5(a) is a still image of indium bumps on metal electrode pads, before reflow, using an in situ reflow camera in an ICP (inductively coupled plasma) system, according to one or more embodiments of the present invention;

FIG. 5(b) is a still image of indium bumps on metal electrode pads, after reflow, using an in situ reflow camera in an ICP system, according to one or more embodiments of the present invention;

FIG. 6(a) is a still image from a real time movie of indium bumps on metal electrode pads, before reflow, using an in situ reflow camera in an ICP system, according to one or more embodiments of the present invention;

FIG. 6(b) is a still image from a real time movie of indium bumps on metal electrode pads, after reflow, using an in situ reflow camera in an ICP system, according to one or more embodiments of the present invention;

FIG. 7(a) is a real time image of indium bumps on a detector read out, before reflow, using an in situ reflow camera in an ICP system, according to one or more embodiments of the present invention;

FIG. 7(b) is a real time image of Indium bumps on a detector read-out, after reflow, showing dome shaped indium bumps, and using an in situ reflow camera in an ICP system, according to one or more embodiments of the present invention; FIG. 8 is a streak free image obtained from an imager/read out pair whose indium bumps were reflowed into domes, where the imager bumps are nearly two years old, according to one or more embodiments of the present invention;

FIG. 9 is a flowchart illustrating a method of fabricating solder bumps, according to one or more embodiments of the present invention;

FIG. 10 is a flowchart illustrating a method of optimizing a solder bump reflow process, according to one or more embodiments of the present invention;

FIG. 11 is a cross-sectional schematic of a device according to one or more embodiments of the present invention; and

FIG. 12(a) shows a solder bump having a truncated sphere shape and FIG. 12(b) shows a solder bump having a dome shape, according to one or more embodiments of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

One or more embodiments of the present invention include both a process for removing indium oxide from indium bumps used in flip chip hybridization (bump bonding), a process for reflowing these indium bumps into a highly wetted configuration (dome shape) versus less desirable unwetted shapes (rectangles or spheres), and a way to monitor this transition in real time. This is the first known demonstration of the production of indium “domes” for hybridization. The reflow and indium oxide removal processes are attained by exposing detector and readout samples, with indium bumps, to a hydrogen plasma. Camera and telescoping zoom lens are mounted to a microscope boom stand outside the plasma chamber and image the bumps in real time. The bump morphology is monitored in real time during the plasma treatment process, and treatment is shut off when the desired reflow and morphology has been achieved.

Technical Description

Atomic hydrogen reacts with indium oxide at relatively moderate temperatures to form indium metal and volatile water vapor. In a plasma system at reduced pressures, atomic hydrogen is formed, and the resulting water vapor is pumped away to yield a pristine indium metal bump. Under the right conditions, a moderate hydrogen plasma exposure raises the temperature of the indium bump to the point where the indium bump flows. This flow results in a desirable shape where indium efficiently wets the metal contact pad to provide good electrical contact to the underlying readout or imager circuit, respectively. However, it is extremely important to carefully control this process, as the intensity of the hydrogen plasma treatment dramatically affects the indium bump morphology. High power or long exposure times lead to the indium metal sputtering or evaporating, causing the bump to shrink or disappear. Low power exposures may not remove the oxide, or can yield undesirable morphologies (such as piles of multiple small spheres).

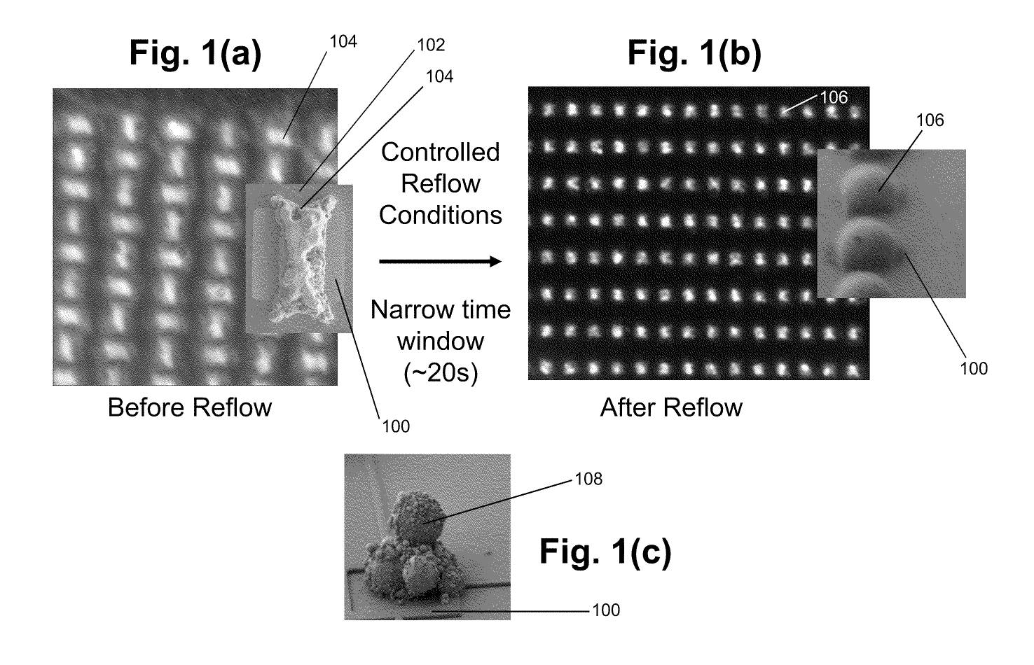

FIG. 1(a) illustrates a metal electrical contact pad 100 that is lithographically patterned on a device 102, and a solder bump bar 104 that is misaligned and at least partially positioned on the surface of the metal electrical contact pad 100.

FIG. 1(b) illustrates the solder bump bar 104 has transformed into having a spherical shape 106 after controlled reflow, wherein the controlling corrects for imperfect alignment of the solder bump bar 104 relative to the metal electrical contact pad 100. FIG. 1(b) illustrates that the controlling achieves the solder bump 106 that is contained on the metal electrical contact pad 100.

FIG. 1(c) illustrates an embodiment where longer reflow conditions at lower plasma power (as compared to FIG. 1(b)) lead to a solder bump 108 that has poor wetting (a pile of multiple small spheres) to the metal electrode pad 100.

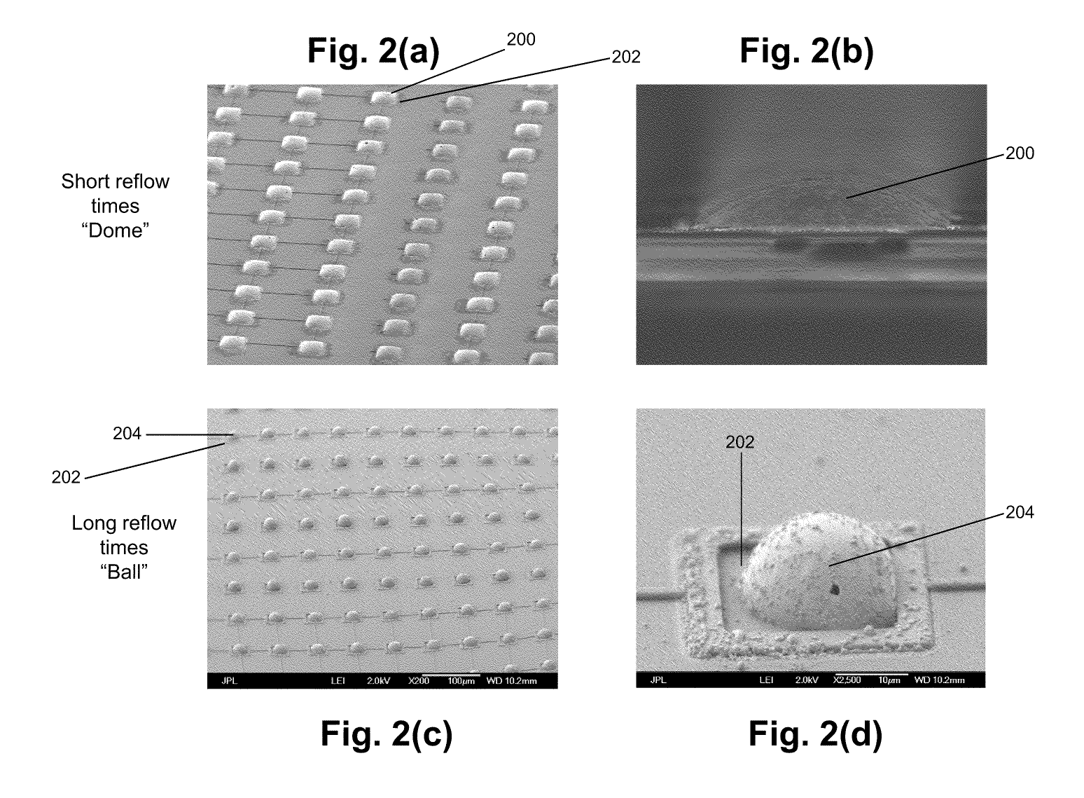

FIGS. 2(a)-2(d) illustrate the effect of reflow time. In the embodiment of FIG. 2(a), short reflow conditions lead to a dome shape solder bump 200, on the metal electrode pad 202, that has a height (at the top-most vertex) of 6-7 micrometers and a superior morphology. FIG. 2(b) is a close up view of FIG. 2(a) showing a single indium bump 200 that is a dome shape, having a dome height (at the top-most vertex) that is 6-7 micrometers tall according to one or more embodiments of the present invention.

FIG. 2(c) illustrates that longer reflow conditions (as compared to FIG. 2(a)) lead to a ball shape solder bump 204, on the metal electrode pad 202. FIG. 2(d) is a close up view of FIG. 2(c) showing a single indium bump 204 that is a ball shape, according to one or more embodiments of the present invention.

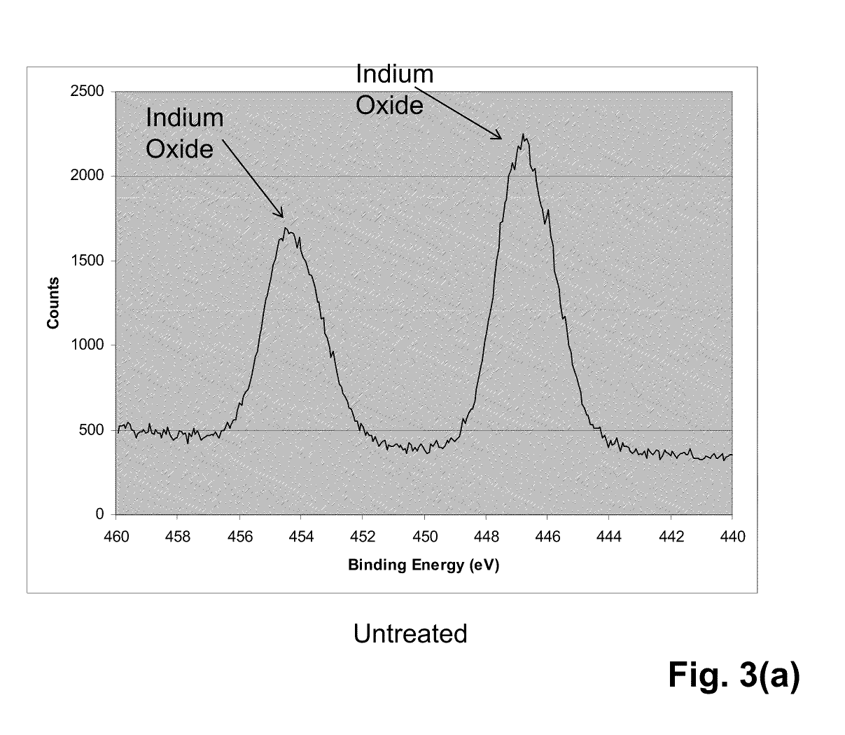

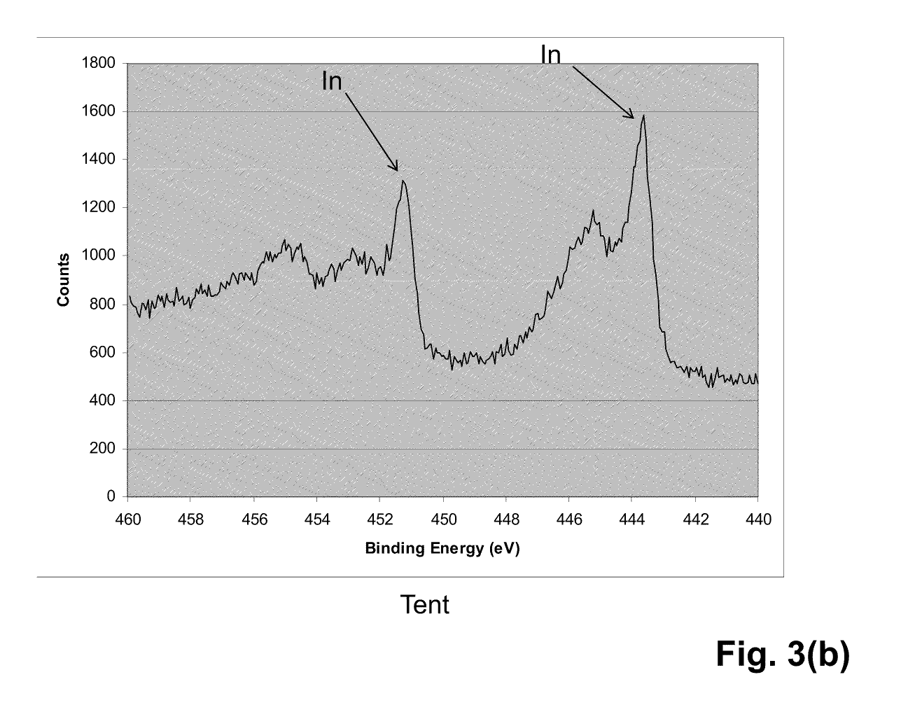

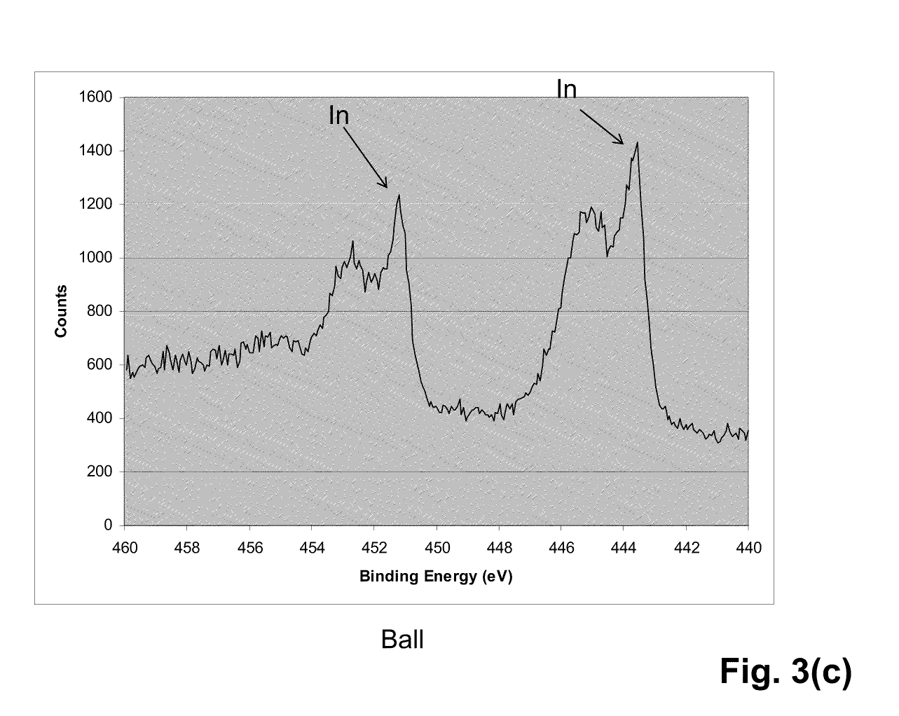

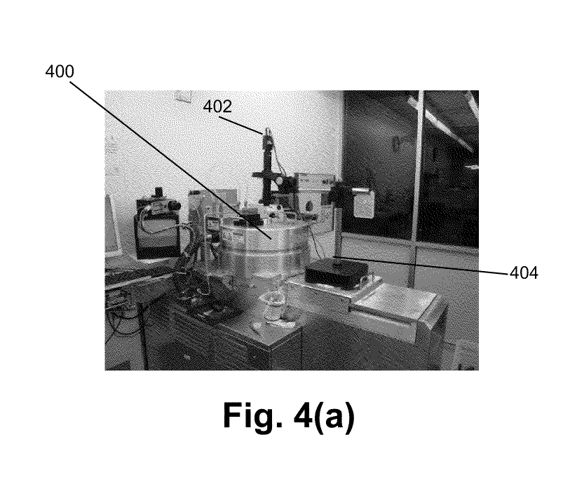

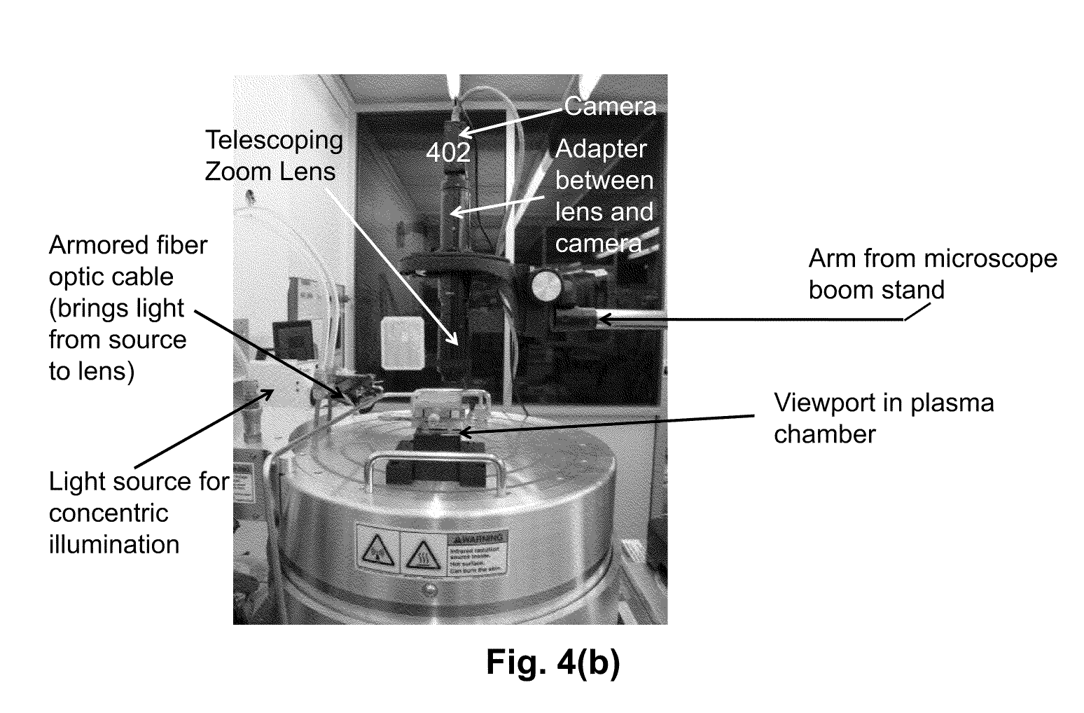

FIGS. 3(a)-(c) illustrate XPS results showing that metallic indium is present in the bumps regardless of dome or ball morphology. The dome morphology appears to have a slightly higher indium metal/oxide ratio (however, this could also be a function of air exposure time).

The sharp peaks in FIG. 3(a) indicate indium oxide (or In₂O₃) (e.g., as indicated by the arrows), and the sharp peaks in FIGS. 3(b)-(c) (e.g., as indicated by the arrows) indicate the presence of metallic indium (In).

To ensure the fine tuning of the reflow process, it is necessary to have real time feedback on the status of the bumps. A commercially available, off the shelf, zoom lens enables real time feedback to ensure the best reflow conditions.

FIGS. 4(a) and 4(b) illustrate an apparatus for forming one or more solder bumps and a configuration of optics and imaging equipment than enables imaging solder bumps. The apparatus comprises a processing apparatus (plasma chamber) for heating and reflowing the solder bumps; and optics (e.g., telescoping zoom lens, optical fiber, light source, boom stand) positioned to view and image solder bumps positioned on material in the processing apparatus.

The optics and imaging equipment may be positioned to enable monitoring of the reflow and heating of the solder bumps in real-time, and e.g., remotely from outside a processing chamber or apparatus (e.g., plasma processing chamber), or inside the processing chamber or apparatus.

The apparatus of FIGS. 4(a)-4(b) includes a plasma chamber 400 for heating and reflowing the solder bumps by exposing the solder bumps on one or more materials in the plasma chamber with plasma, and a camera 402 positioned (e.g., on a boomstand 404) to view solder bumps positioned on the material in the plasma chamber 400.

FIG. 4(b) further illustrates a telescoping zoom lens for imaging the solder bumps on a camera, a light source for concentric illumination of the solder bumps in the plasma chamber, an armored fiber optic cable bringing light from the light source to the telescoping zoom lens, an adapter between the telescoping zoom lens and the camera for mating the telescoping zoom lens to the camera, an arm from a microscope boom stand to hold the telescoping zoom lens and camera, and a viewport in the plasma chamber. The housing for the light source (external illumination) is concentric with the lens, so that the solder bump sample is illuminated from around the lens, enabling light from the side to reflect off the solder bump sample and be collected for viewing in the camera. Thus, the concentric illumination illuminates the sample with light that reflects off the solder bumps, wherein the light reflected off the solder bumps is collected by the optical fiber and imaged by the lens on the camera (to image the solder bumps).

In one or more embodiments of the present invention, the appropriately placed viewport in the plasma chamber 400 images a small field (e.g., a square of approximately 5 millimeters on each side) of the bumps (e.g., 10-20 microns in size) during the hydrogen plasma reflow process. By monitoring the shape of the bumps in real time using the video camera mounted to, for example, the telescoping 12× magnifying zoom lens and associated optical elements, embodiments of the invention can precisely determine when the reflow of the bumps has occurred, and shut off the plasma before evaporation or dewetting takes place.

In one or more embodiments of the present invention, the zoom lens has a focal distance (e.g., of thirteen (13) inches), allowing the remote mounting of the camera 402 outside the plasma chamber 400.

In one or more embodiments, the camera used is a 5 Mega Pixel Tuscen™ microscope digital USB 2.0 color camera with video and measurement function, and the lenses and lens attachments for use in the telescoping zoom lens are from Navitar™ and include a 12× zoom lens with 3 mm fine focus and co-axial illuminator with aperture (Part No. NAV 1-50487), a 3.5× short adapter (Part No. NAV 1-62831), a C-mount coupler (Part No. NAV 1-6010), a 12× lens attachment 0.25× (Part No. NAV 1-50011, a mounting plate for 12× system (Part No. NAV 1-50228), a microscope carrier (Part No. 10445617), a focus drive with 500 mm column (Part No. 10446100), and an MCB custom base plate to attach to the base of the 500 mm column and to fit atop the plasma tool or chamber. This series of lenses and attachments enables a focal distance of ˜13 inches and resolution of features that are ˜5 microns in size, for example (the invention is not limited to these components, focal distances and resolution, which are merely provided as examples).

Such a reflow process according to the present invention has been demonstrated to yield streak free imagers, and repair misaligned, or otherwise damaged indium bumps.

In other embodiments, the processing apparatus may be a vessel or container (closed or open) where reflowing and heating of solder bumps on the material occurs. The processing apparatus may include means for supporting and reflowing the material with solder bumps, e.g., a sample holder for holding the material with solder bumps, and heater, hot plate, or laser source coupled to the sample holder for heating, reflowing, or melting the solder bumps into the desired morphology for improved wetting, and a processor for controlling the output of the hot plate, heater, or laser source to reflow the solder bumps controllably .

A processor (e.g., computer processor) may be used to vary one or more of a power, pressure, and exposure time of the plasma incident on the solder bumps, in response to an image of the solder bumps obtained from the camera 402. The monitoring in real time may use a camera 402 that is integrated into the plasma chamber 400, so that monitoring and controlling may be performed automatically. The processor may be programmed to produce conditions that achieve a highly wetted condition (e.g., 100% wetting) for the solder bumps, for example.

Camera Images Monitoring The Reflow

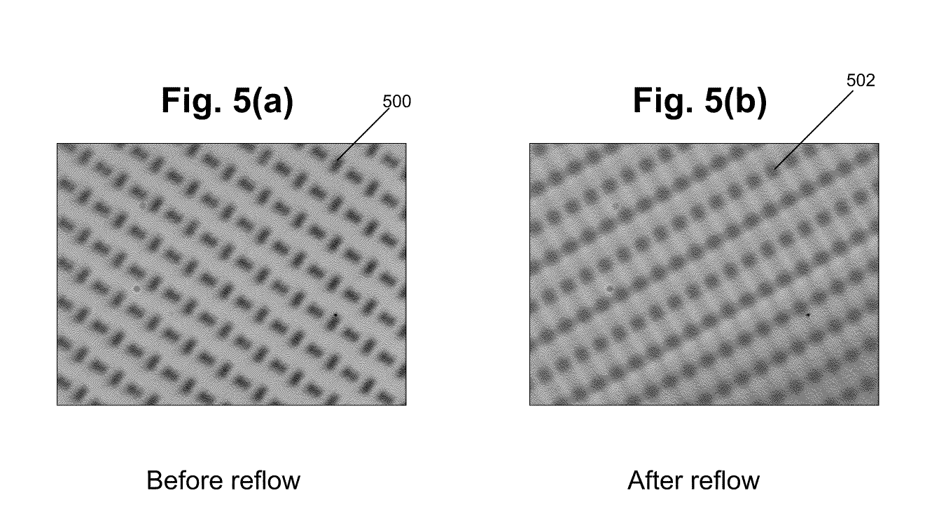

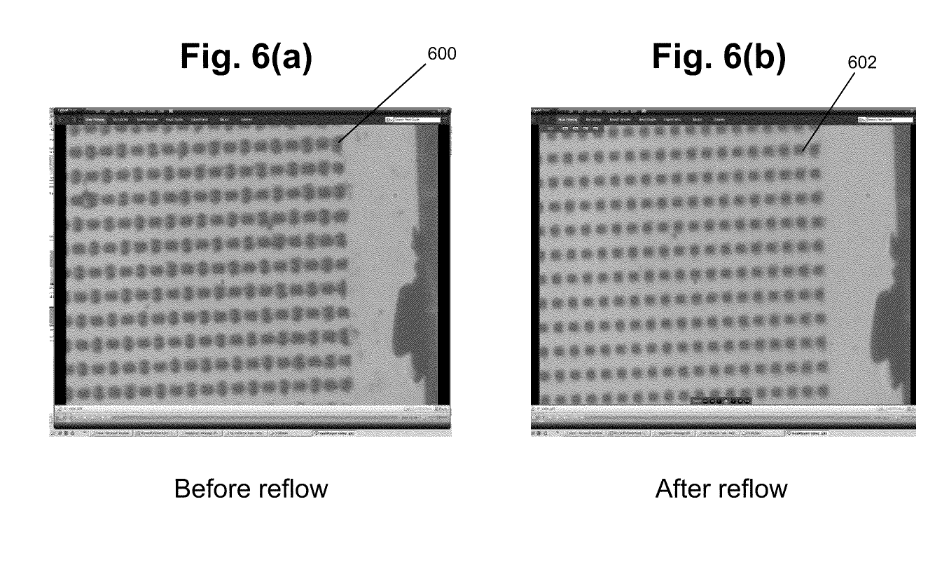

FIGS. 5(a) and 6(a) are a still image, and a still image from a real time movie, respectively, of bar shaped indium bumps 500, 600 on metal electrode pads, before reflow, using an in situ reflow camera viewing an ICP system.

FIGS. 5(b) and 6(b) are a still image, and still image from a real time movie, respectively, of improved morphology indium bumps 502, 602 on metal electrode pads, after reflow, using an in situ reflow camera in an ICP system.

Thus, the camera can operate at video rate speeds. In one or more embodiments, the camera may have a resolution that is at least three (3) times, or at least ten (10) times larger than a size of the solder bumps prior to the plasma treatment or heating and reflowing. For example, the resolution may be at least a factor of one-hundred (100) times better than the geometry of the solder bumps.

Fabricated Devices

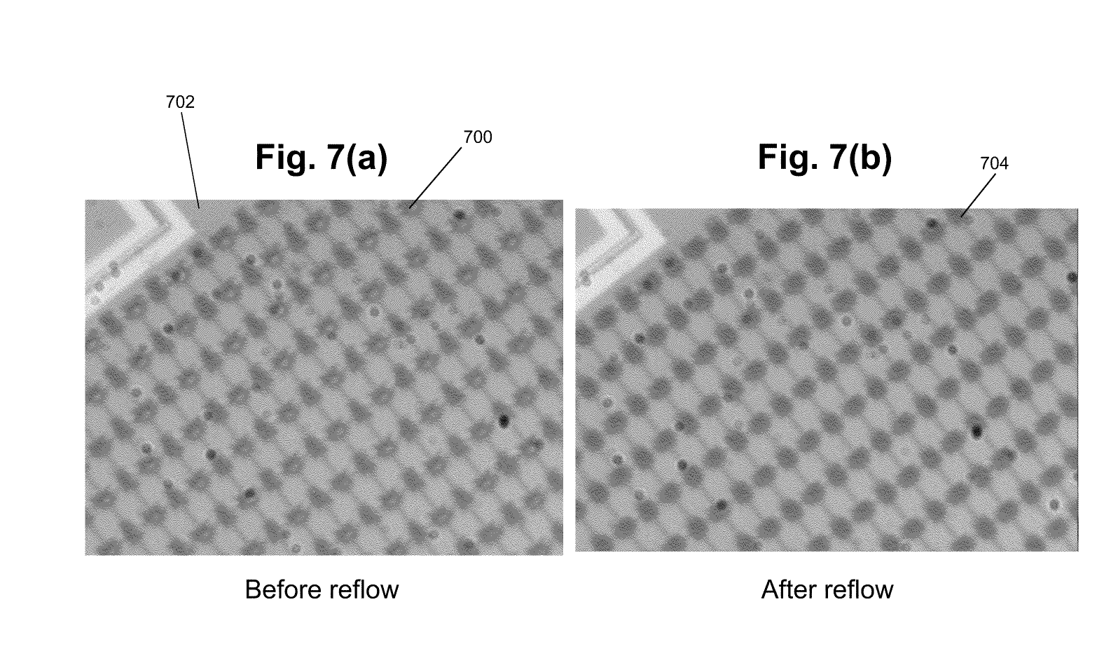

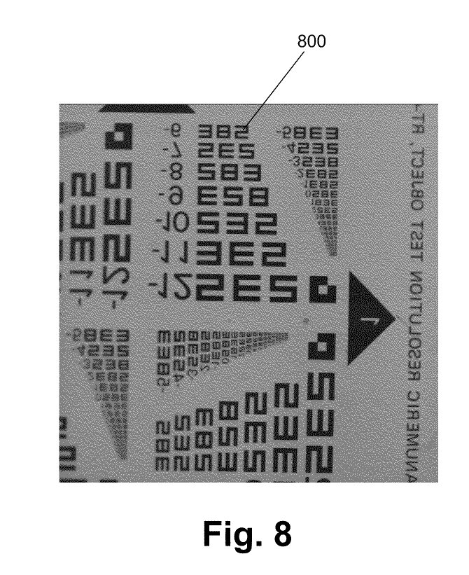

FIG. 7(a) is a real time image of indium bumps 700 on a detector read-out 702 before reflow, and FIG. 7(b) is a real time image of indium bumps 704 after reflow, showing dome shaped indium bumps 704, wherein the images are taken using an in situ reflow camera in an ICP system.

FIG. 8 illustrates streak free images of letters and numbers 800 imaged by an imager fabricated using a method of embodiments of the present invention. The imager is bonded using reflowed indium bumps, to a substrate readout, face to face.

Process Steps

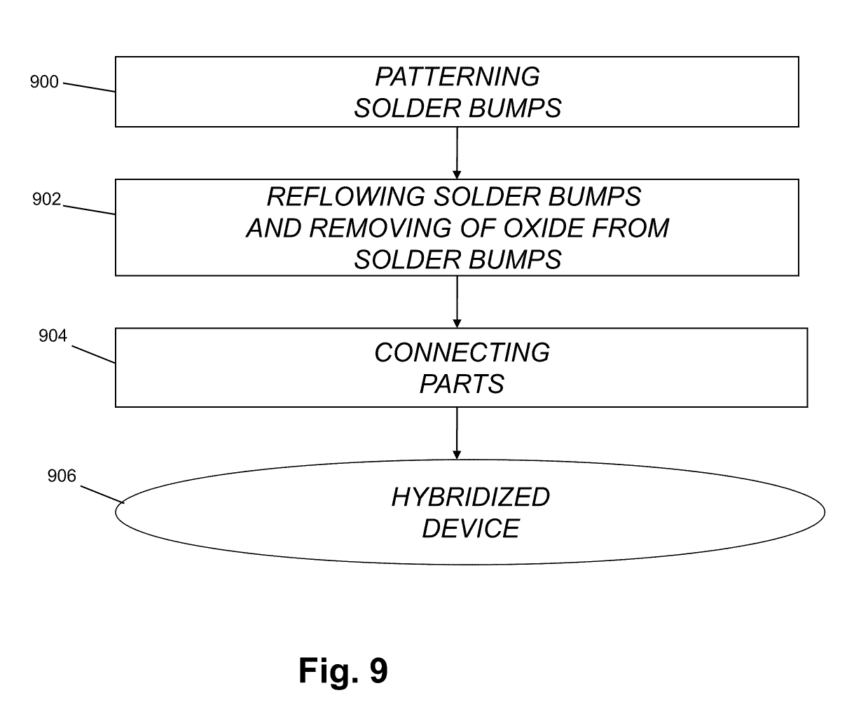

FIG. 9 illustrates a method of forming one or more solder bumps on one or more materials, wherein the materials may include multiple parts of a device (e.g., a first part and a second part of a device). The method may comprise one or more of the following steps.

Block 900 represents patterning and/or positioning the solder bumps, e.g., on one of the parts only (e.g. on the first part only), or on both or all of the parts (e.g., on the first part and the second part). The material may be one or more metal electrical contact pads that are lithographically patterned on a device and the solder bump may be misaligned, aligned (or stenciled) and at least partially positioned on the surface of the metal electrical contact pad. The solder bump may be indium, tin, or other solder materials, metals, or alloys. The solder may be a material or metal or alloy having a melting temperature greater than 150° C.

Block 902 represents reflowing or melting the solder bumps and optionally also removing oxide from the solder bumps, e.g., using a plasma treatment in a plasma chamber.

Block 904 represents connecting (e.g., electrically connecting) the second part to the first part using the solder bumps.

Block 906 represents the end result of the method, a hybridized device. In one embodiment, the device comprises parts of the device; and one or more solder bumps connecting at least two of the parts, wherein the solder bumps are maximally wetted to at least one of the parts so that a contact angle of the solder bump with respect to the at least one of the parts is as close to zero as possible. The parts may include device chips, wherein solder bumps may be formed (and controllably re-flowed) on each chip separately (one chip at a time) to form a desired morphology of the solder bumps (e.g., domes), and then the solder bumps on each chip may be aligned before the chips are connected or bonded using the solder bumps. However, solder bumps may be formed or positioned on one part of the device only, and the part with solder bumps may be connected to a second part without solder bumps. The device may be a microelectronic, nanoelectronic device, or microelectromechanical (MEMS) device, for example. The device may be a semiconductor (e.g., silicon) device or chip (e.g., a semiconductor chip capable of reading out the image information collected by the detector). The parts may include a substrate (e.g., read out, or substrate, e.g., silicon substrate) and a detector, for example.

In yet other embodiments, the parts may be connected or bonded or compressed to seal a volume or vacuum inside. The present invention is not limited to particular devices or materials on which the solder is deposited.

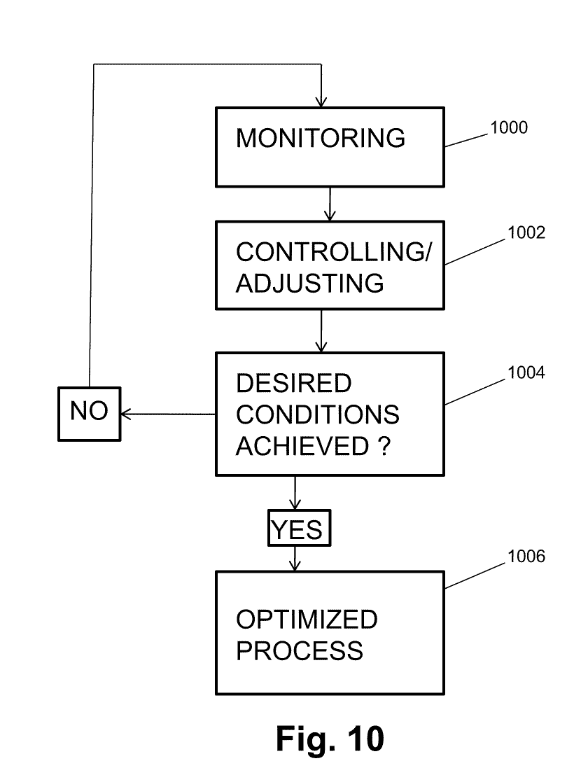

FIG. 10 is a flowchart illustrating a method for optimizing the process of FIG. 9. The reflowing step of Block 902 may comprise the following steps.

Block 1000 represents monitoring the reflowing or melting 902 of the solder bumps in real time. The monitoring may be by use of an optical camera that is positioned to view or optically image the solder bumps in the processing apparatus or plasma chamber. However, the present invention is not limited to optical imaging. Infrared or ultraviolet imaging could be used for example. In other embodiments, the monitoring uses scattering of laser beam from the solder bumps.

Block 1002 represents controlling or adjusting the reflowing or melting in real time (e.g., based on the monitoring 1000, or observations of the monitoring 1000, for example), thereby controlling and/or optimizing the morphology of each of the solder bumps and/or wetting of the solder bumps to one or more surfaces of one or more materials in real time. The controlling may correct for imperfect alignment of the solder bump(s) relative to one or more metal electrical contact pads. For example, the metal electrical contact pads may include one or more squares of conductive metal (e.g., having a ten (10) micron side length) that are lithographically patterned or stenciled on a device chip. A solder bump in a shape of a bar may be patterned on each of the squares. Imperfect alignment may include situations where the bar is only partially on the metal square, or is not centered on or is offset with respect to the metal square. However, using one or more embodiments of the controlled reflow process of the present invention, the solder bump may controllably melt or transform so that it stays contained on or fully wets the conductive metal square pad. The controlling may also center the solder bump on the metal contact pad.

As the bar reflows or melts, the monitoring step 1000 observes how the shape of the bar changes. In one embodiment, as the melting proceeds (i.e., as time increases), the shape may change from a bar, to a pyramid, tent, or peaked shape, to a truncated sphere on a pad (e.g., a sphere/ball that is bisected by a pad/planar surface), to a perfect sphere or ball on a pad, or ball with a flat surface contacting the pad, before the solder bump eventually shrinks, evaporates and disappears. The size of the pad may further determine whether the shape extends or protrudes beyond a virtual boundary extending/defined from/by the sides of the pad (e.g., similar to a bulging ball/balloon on a flat surface). In some embodiments, the transformation of the solder bumps from bar shape to spherical shape may occur within 5-10 seconds.

For some embodiments, the controlling 1002 may be used to obtain a pyramidal shape. For other embodiments, it may be preferable to obtain a solder bump that is a sphere, spherical, hemispherical, or a truncated sphere (e.g., a ball with a flat base where the sphere is bisected by a flat base/planar surface/pad) shape. The actual desired shape or morphology may depend on the volume of the solder that is deposited, or the materials upon which the solder is deposited. Thus, one or more embodiments of the present invention may achieve the morphology that is a pyramid shape, a dome shape, a spherical shape, a truncated sphere, or a shape between a pyramidal or dome shape and a spherical shape, for example.

The metal pad size may determine the contact area with the solder bump.

In other embodiments, the controlling 1002 may increase, improve, or optimize the wetting, e.g., maximizing wetting of the solder bump to the surface of the material or obtaining a highly wetted configuration. In this regard, wetting may be 100%, or contact of the indium to the metal pad may be 100%, for example. In some embodiments, if the area to be contacted is ten (10) microns squared, embodiments of the invention enable at least one (1) micron square of the solder bump to be wetting.

For example, if the volume of solder is so large that the solder flows off the desired contact area, the present invention may provide wetting conditions that restrain flow and prevent the solder bump from flowing off the contact pad, allowing the solder bump to stay on the contact pad. A dome shaped solder bump may have the same lateral dimensions as the contact pad, while maintaining a high volume. Some morphologies for the solder bump (e.g., sphere on a square contact pad) prevent the solder from flowing to unwanted locations.

The controlling 1002 may form the solder bump in a position that is most thermodynamically stable, for example. In some embodiments, if the reflow is allowed to proceed for too long a time, the solder bump may ball up and wetting may worsen or be reduced. In other embodiments, it may be desirable to maintain a sufficiently high amount of solder material to achieve a spherical shape while maintaining wetting to the square shaped contact pad.

Wetting is typically characterized by the contact angle of the solder to the material on which the solder sits. Wetting increases as the contact angle reduces to zero (i.e., a contact angle of 0° is perfect wetting, and a contact angle of 180° is perfectly non-wetted).

The controlling 1002 may vary (e.g., using a computer processor) one or more of a power, pressure, and exposure time of a plasma that is used to reflow and heat the solder bumps. The plasma may include hydrogen, a forming gas, or reducing gas, or gas mixture, for example. The power that is varied or controlled may include the power needed to create the plasma (thereby determining the degree of dissociation and ionization, and/or density of the plasma, or amount of plasma/reactive species created) and/or the power of the plasma incident on the solder bumps (thereby controlling the intensity or energy at which the ionized species come into contact with the solder bumps or device part). The power may be used to control the degree of focusing of the plasma on the device part or solder. In one embodiment, the power needed to create the plasma is approximately 500 W, and the power of the plasma incident on the solder bump is 250 W.

Exemplary process parameters for use with a Unaxis™ Inductively Coupled Plasma (ICP) etching system (Model:=SLN-ICP Shuttleline) include ICP power (250 W), bias power (50 W), gas (50 sccm) H₂, and pressure (30 millitorr).

However, these powers and process parameters are merely for illustration and may vary depending on the type of equipment used.

The controlling 1002 may include varying the exposure time of the solder or device part to the plasma, e.g., in a computer processor. In one or more embodiments, the exposure time is less than twenty (20) seconds, for example, five to ten (5-10) seconds. However, the exposure time may be adjusted by reducing or otherwise adjusting the power. Embodiments of the invention are not limited to particular powers or exposure times since the reflow can be monitored in real time and the powers/exposure times, etc. can be adjusted/calibrated to achieve a desired result. The monitoring system may be used to change any parameters that affect morphology and/or wetting of the solder bumps. For example, the treatment may be shut off when the desired morphology is obtained.

Embodiments of the invention are not limited to the use of plasma to reflow or melt the solder bumps. Other methods, or other reactive species, or processing apparatus that achieves melting, heating, or reflow of solder bumps may also be used.

Thus, the above steps include treating the solder bumps, and monitoring a shape of the solder bumps in real time, wherein the treatment may be modified (e.g., power or exposure time modifications) depending on observations of the monitoring step. In this way, the present invention may treat components, observe what is achieved, and modify the process parameters as necessary (e.g., using a feedback loop). The results may be obtained in seconds, for example.

Block 1004 is a decision box that asks and determines whether desired conditions have been achieved (e.g., whether desired solder bump morphology or wetting has been obtained or achieved). If yes, and the condition of the desired solder bumps morphology or wetting is achieved, the process is optimized (Block 1006) and the process stops. If no, and the desired conditions (solder bump morphology or wetting) is not achieved, the monitoring 1000 and controlling 1002 steps may be repeated any number of times, and iteratively, as necessary until the desired result or conditions (e.g., solder bump morphology or wetting) are obtained or achieved.

The monitoring 1000, controlling 1002 of reflow, and removal of oxide may all happen at the same time. However, it is not necessary that oxide is removed.

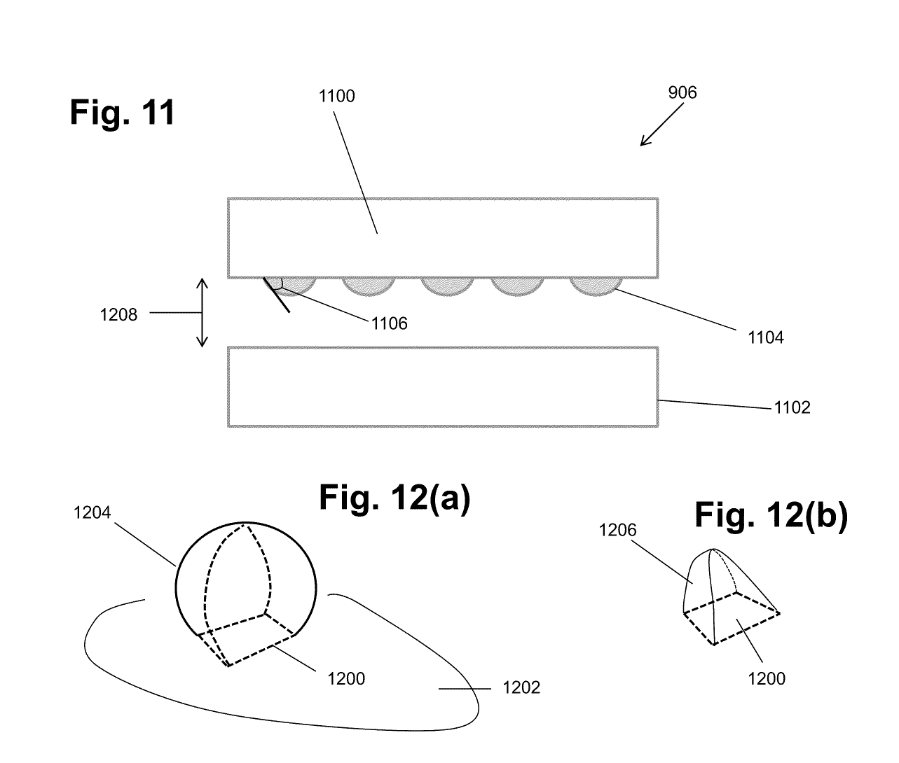

FIG. 11 illustrates a method for fabricating a device 906 comprising a first part 1100 and a second part 1102; positioning 900 solder bumps 1104 on the first part only 1100 or on both the first part 1100 and the second part 1102; performing the reflowing 902, monitoring 1000, and controlling 1002 steps so that the solder bumps 1104 (truncated sphere shape) are maximally wetted to at least one of the parts 1100 such that a contact angle 1106 of the solder bump 1104 with respect to the at least one of the parts 1100 is as close to zero as possible; and connecting 904/1108 the second part 1102 to the first part 1100 using the solder bumps 1104.

FIG. 12(a) shows a square metal contact pad 1200 on a material or part of a device 1202, and the solder bump having a truncated sphere shape 1204 (larger than a hemisphere) wetting or contacting the metal contact pad 1200 without contacting or wetting regions of the material 1202 outside the contact pad 1200. FIG. 12(b) shows a solder bump having a pyramidal or dome shape 1206.

Advantages and Improvements

Embodiments of the present invention provide: (1) real time monitoring of indium bump reflow; and (2) reflow process control to obtain bumps in a “dome” configuration. For some materials, the “dome” configuration is a substantial improvement over the existing technology to produce “spheres”, because the indium “dome” display better wetting to the underlying pads fabricated from certain materials. However, for other materials, different shapes of the indium bumps may be desirable. Thus, embodiments of the invention are not limited to particular shapes of the indium bumps; rather one can produce any desired indium or solder bump shape depending, e.g., on the desired wetting or application. For example, solder shapes with peaks (e.g., dome or pyramidal shapes) or spherical shapes may be obtained in a controlled (e.g., not haphazard) fashion. Moreover, embodiments of the invention are not limited to the use of indium solder bumps—other solder materials may also be used.

Real time reflow monitoring may be essential to obtain the desired morphology because the process window for plasma treatment is only a matter of seconds and depends strongly on the time history of air exposure of the parts to by hybridized. There is a wide variability in the time needed to expose the oxidized indium to the plasma due to the potentially different thickness of the oxide layer. Without the ability to monitor when the bumps are ready the oxide layer may not be removed or the energy input may overshoot and vaporize the indium.

### CONCLUSION

This concludes the description of preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of forming one or more solder bumps on one or more materials comprising:
(a) reflowing the solder bumps;
(b) monitoring the reflowing of the solder bumps in real time; and
(c) controlling the reflowing in real time, based on the monitoring, thereby controlling and optimizing a morphology of each of the solder bumps.

2. The method of claim 1, wherein the monitoring is used to control wetting of the solder bumps to one or more surfaces of one or more materials in real time.

3. The method of claim 2, wherein the controlling optimizes or maximizes the wetting of the solder bumps to the surfaces of the materials.

4. The method of claim 1, wherein the solder bumps are indium solder bumps.

5. The method of claim 1, wherein the monitoring is using an optical camera that is positioned to view the solder bumps.

6. The method of claim 1, wherein the materials include one or more metal electrical contact pads that are lithographically patterned on a device, and the solder bumps are at least partially positioned on the surfaces of the one or more metal electrical contact pads.

7. The method of claim 6, wherein the controlling corrects for imperfect alignment of the solder bumps relative to the one or more metal electrical contact pads.

8. The method of claim 6, wherein the controlling achieves the solder bumps that are contained on the one or more metal electrical contact pads.

9. The method of claim 1, further comprising:
at least two of the materials including a first part and a second part of a device;
positioning the solder bumps on the first part only, prior to the step (a); and
connecting the second part to the first part using the solder bumps.

10. The method of claim 1, further comprising:
at least two of the materials including a first part and a second part of a device;
positioning the solder bumps on the first part and the second part, prior to the step (a); and
connecting the second part to the first part using the solder bumps.

11. The method of claim 1, wherein the controlling achieves the morphology that is a dome shape, a spherical shape, a truncated sphere, or a shape between a dome shape and a spherical shape.

12. The method of claim 1, wherein the controlling varies one or more of a power, pressure, and exposure time of a plasma incident on the solder bumps.

13. The method of claim 12, wherein the plasma is forming gas or hydrogen.

14. The method of claim 12, wherein the plasma is a reducing gas or gas mixture.

15. The method of claim 12, further comprising using the plasma to remove an oxide from the solder bumps.

16. An apparatus for forming one or more solder bumps comprising
a processing apparatus for heating and reflowing the solder bumps; and
optics positioned to view and image solder bumps positioned on material in the processing apparatus.

17. The apparatus of claim 16, wherein the processing apparatus is a plasma chamber and the heating and the reflowing results from exposing the solder bumps to plasma in the plasma chamber.

18. The apparatus of claim 17, further comprising a computer processor for varying one or more of a power, pressure, gas composition, and exposure time of the plasma incident on the solder bumps, in response to an image of the solder bumps obtained from the camera.

19. The apparatus of claim 16, wherein the optics includes a camera operating at video rate speeds and has a resolution that is at least ten (10) times larger than a size of the solder bumps prior to the heating and the reflowing.

20. The apparatus of claim 16, wherein the optics is positioned to enable monitoring of the reflowing and heating of the solder bumps in real-time and remotely from outside the processing apparatus.

21. A device, comprising:
parts of the device; and
one or more solder bumps connecting at least two of the parts, wherein the solder bumps are maximally wetted to at least one of the parts, so that a contact angle of the solder bump with respect to the at least one of the parts is as close to zero as possible.

22. The device of claim 18, wherein the device is a microelectronic, a nanoelectronic device, or a microelectromechanical (MEMS) device.

23. The device of claim 18, wherein the parts include a substrate and a detector.

24. The device of claim 20, wherein the substrate is a semiconductor chip capable of reading out the image information collected by the detector.
